(19) United States
(12) Patent Application Publication
(10) Pub. No.: US 2026/0299032 A1
(43) Pub. Date: Oct. 1, 2026

(54) STATE-OF-CHARGE ESTIMATION USING EMBEDDABLE DISTRIBUTED ELECTRO-THERMAL MODELS

(71) Applicant: Caterpillar Inc., Peoria, IL (US)

(72) Inventors: Leo Roger Edward Shead, Peterborough (GB); Craig Cox, Sheffield (GB); Sunil K. Rawat, London (GB)

(73) Assignee: Caterpillar Inc., Peoria, IL (US)

(21) Appl. No.: 19/480,703

(22) PCT Filed: Jan. 22, 2024
(86) PCT No.: PCT/US2024/012388

§ 371 Date: Oct. 31, 2025

(30) Foreign Application Priority Data
May 11, 2023 (GB) 2306983.4

(51) Int. Cl. G01R 31/367; G01R 31/374; G01R 31/378; G01R 31/3842; G01R 31/396; H01M 10/48

(52) U.S. Cl. CPC G01R 31/367; G01R 31/374; G01R 31/378; G01R 31/3842; G01R 31/396; H01M 10/48

(57) ABSTRACT

A state-of-charge (SoC) estimation of a lithium-ion (Li-Ion) battery using embedded distributed electro-thermal models is provided. Corrections are applied to a localized SoC of each equivalent circuit network (ECN) of a cell calculated in a distributed electrical model and to a localized temperature of each ECN calculated in a distributed thermal model. The SoCs of the ECNs are refined by feeding the corrected localized SoCs and the corrected localized temperatures back to the distributed electrical and thermal models, and an SoC estimation of the cell is generated. A child cell SoC is calculated by applying calculated parameters associated with the SoC estimation of the parent cell to a general cell distribution model, applying correction to the child cell SoC by applying a correction algorithm to the child cell SoC of each child cell, and generating a child SoC estimation of each child cell based on the corrected child cell SoC.

### TECHNICAL FIELD

The present disclosure relates to a system and method for estimating state-of-charge of a lithium ion (Li-Ion) battery, and more particularly, to a system and method for estimating state-of-charge of a Li-Ion battery based on distributed thermal and electrical models of Li-Ion battery cells.

### BACKGROUND

State of charge (SoC) is a level of charge of a battery, such as a Li-Ion battery, relative to its capacity, and may be expressed as a percentage of the capacity, for example, 0% being fully depleted and 100% being fully charged. Various methods for modeling a Li-Ion battery to estimate the SoC online have been proposed and developed, which comprise of a lumped electrical and thermal approach coupled with an estimator. However, lumped models may not capture the actual distributed nature of the charge and resistance within a cell which strongly influence the overall state-of-charge of the cell. Accurate modeling of a Li-Ion battery, however, is complicated due to the inhomogeneous nature of the charge within the cell which is influenced by the network of resistance throughout the jellyroll structure as well as the localized temperature of the region. In addition, the cell cooling arrangement will give rise to thermal gradients within the cell, which will lead to current inhomogeneities, localized degradation including resistance increase, and inhomogeneous current heating leading to further thermal gradients. State-of-the-art battery management systems (BMS) do not presently attempt to model internally distributed electrical and/or thermal phenomena.

Reference [1]“the '509 patent” describes a joint estimation method of the state of charge (SOC), state of health (SOH), and power state (state of function, SOF) of a Li-Ion battery, including on-line estimation of the SOH of the battery using the recursive least squares (RLS) method with forgetting factor to identify the open circuit voltage (OCV) and internal resistance on-line. The pre-established OCV-SOC correspondence indirectly obtains the state of charge, and then the battery capacity according to the accumulated charge and discharge between the two SOC points are estimated. On-line estimation of the battery SOC is improved utilizing the Kalman filter algorithm based on the second-order RC equivalent circuit model and updating the battery capacity parameters in the Kalman filter algorithm according to the battery capacity estimation result.

Although the '509 patent describes an estimation method for the SOC, SOH, and SOF of a Li-Ion battery on-line using a second-order RC equivalent circuit model of the Li-Ion battery, the estimation method models a battery as a lumped unit.

The systems and methods described herein are directed to addressing one or more of the drawbacks set forth above. References [2], [3], & [6] describe the PyECN (Python Equivalent Circuit Network) an open-source distributed modelling method developed and used by the Electrochemical Science and Engineering group (ESE) of Imperial College London (ICL) which is also used to form the distributed electro-thermal cell model element described herein. References [3]& [6] describe how such a model can be adapted for on-line state-of-charge and temperature estimation, respectively.

### SUMMARY

According to a first aspect, a method for estimating a state of charge of a lithium-ion battery using embedded distributed electro-thermal models is provided. A state-of-charge estimation of a lithium-ion battery using embedded distributed electro-thermal models is provided. A distributed electrical model of a cell of a lithium-ion (Li-Ion) battery is generated where the cell is a parent cell and the Li-Ion battery includes a plurality of child cells packaged with the parent cell in a pack, and a distributed thermal model of the cell is generated. Corrections to a localized state of charge (SoC) of each equivalent circuit network (ECN) of a plurality of ECNs of the cell are calculated in the distributed electrical model, and corrections to a temperature of each of the plurality of ECNs are calculated in the distributed thermal model. These corrections are applied and the SoCs of the plurality of ECNs are refined by feeding the corrected localized SoCs and the corrected localized temperatures back to the distributed electrical model and the distributed thermal model, and an SoC estimation of the cell is generated based on the refined SoCs. A child cell SoC of each of the plurality of child cells is calculated by applying calculated parameters associated with the SoC estimation of the parent cell to a general cell distribution model, applying correction to the child cell SoC of each of the plurality of child cells by applying a correction algorithm to the child cell SoC of each of the plurality of child cells, and generating a child SoC estimation of each child cell of the plurality of child cells based on the corrected child cell SoC of each of the plurality of child cells.

According to another aspect, a system for estimating a state of charge of a lithium-ion battery using embedded distributed electro-thermal models is provided. The system includes one or more processors; a SoC estimation module coupled to the one or more processors; one or more sensors coupled to the one or more processors; and memory coupled to the one or more processors, where the memory stores thereon computer executable instructions that, when executed by the one or more processors, cause the one or more processors to perform operations for estimating the SoC of the Li-Ion battery by generating a child SoC estimation of each child cell of the plurality of child cells packaged in the Li-Ion battery based on the corrected child cell SoC of each of the plurality of child cells.

According to yet another aspect, a non-transitory computer-readable storage medium storing thereon computer executable instructions that, when executed by one or more processors, cause the one or more processors to perform operations for estimating the SoC of the Li-Ion battery by generating a child SoC estimation of each child cell of the plurality of child cells packaged in the Li-Ion battery based on the corrected child cell SoC of each of the plurality of child cells.

### BRIEF DESCRIPTION OF THE DRAWINGS

The detailed description is described with reference to the accompanying FIGURES. In the FIGURES, the left-most digit of a reference number identifies the FIGURE in which the reference number first appears. The same reference numbers in different FIGURES indicate similar or identical items.

FIG. 1 illustrates a schematic diagram of a prismatic jellyroll cell of a Li-Ion battery and a geometric model of a segment of the prismatic jellyroll cell.

FIG. 2 illustrates a schematic representation of the distributed electrical model equivalent circuit network (ECN) of a segment of the a prismatic jellyroll cell.

FIG. 3 illustrates examples of model components representing the ECN.

FIG. 4 illustrates a flow chart representing an example process of calculating the state of charge (SoC) of the Li-Ion battery based on the distributed electrical model ECN.

FIG. 5 illustrates a flow chart representing an example process of thermal modeling of the Li-Ion battery based on the distributed thermal model ECN elements.

FIG. 6 illustrates an example process of one of the blocks of FIG. 2 for estimating SoC states and the RC current states of the Li-Ion battery.

FIG. 7 illustrates an example process of one of the blocks of FIG. 5 for estimating temperature states of the Li-Ion battery.

FIG. 8 illustrates a diagram representing an example process of estimating the SoC of the parent cell and child cell(s) based on the distributed electrical model ECN and the distributed thermal model ECN.

FIG. 9 illustrates a block diagram of an example SoC estimation system.

### DETAILED DESCRIPTION

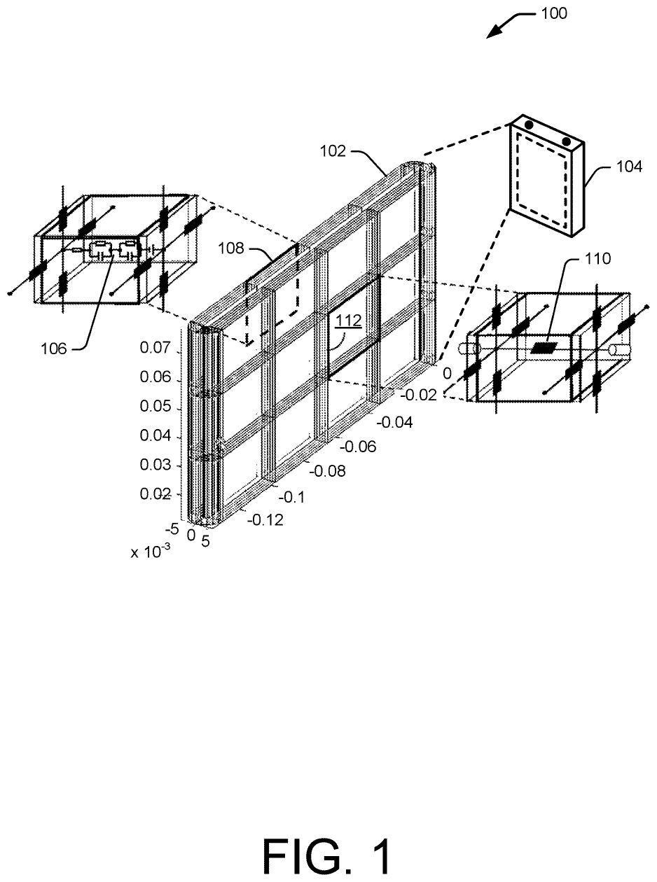

FIG. 1 illustrates a schematic diagram 100 of a prismatic jellyroll cell 102 of a Li-Ion battery 104. The prismatic jellyroll cell 102 may be segmented into a plurality of segments, and each segment may be represented by a geometric model, such as a distributed electrical model equivalent circuit network (ECN) 106 representing a segment 108 and a distributed thermal model ECN 110 representing a segment 112. The prismatic jellyroll cell 102 may be represented by matrices where each element in the matrices represents a geometric model of a corresponding segment of the prismatic jellyroll cell 102. The layered structure of the current collector and the electrode material representative of the real cell are lumped to a manageable resolution.

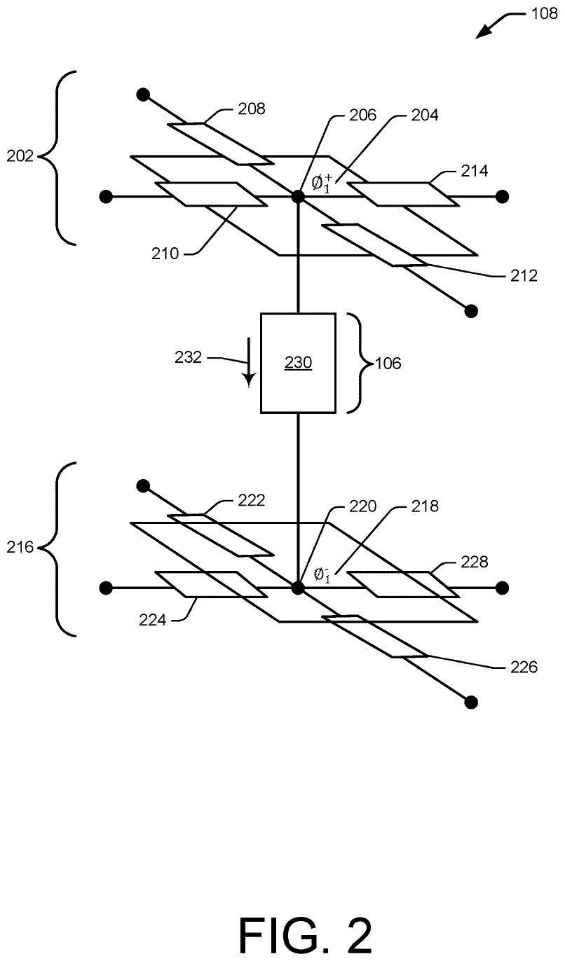

FIG. 2 illustrates a schematic representation of the distributed electrical model ECN 106 of a segment of a plurality of segments of a prismatic jellyroll cell, such as the segment 108 of the prismatic jellyroll cell 102. In this example, an anode 202 of the distributed electrical model ECN 106 is represented as having a potential Ø₁⁺ 204 at a positive node 206 of four anode resistors, 208, 210, 212, and 214. A cathode 216 of the distributed electrical model ECN 106 is represented as having a potential Ø₁⁻ 218 at a negative node 220 of four cathode resistors, 222, 224, 226, and 228. The distributed electrical model ECN 106 is represented as a component 230, having an ECN current, or a sub-model current, 232, and comprising various model components connecting the anode 202 and the cathode 216.

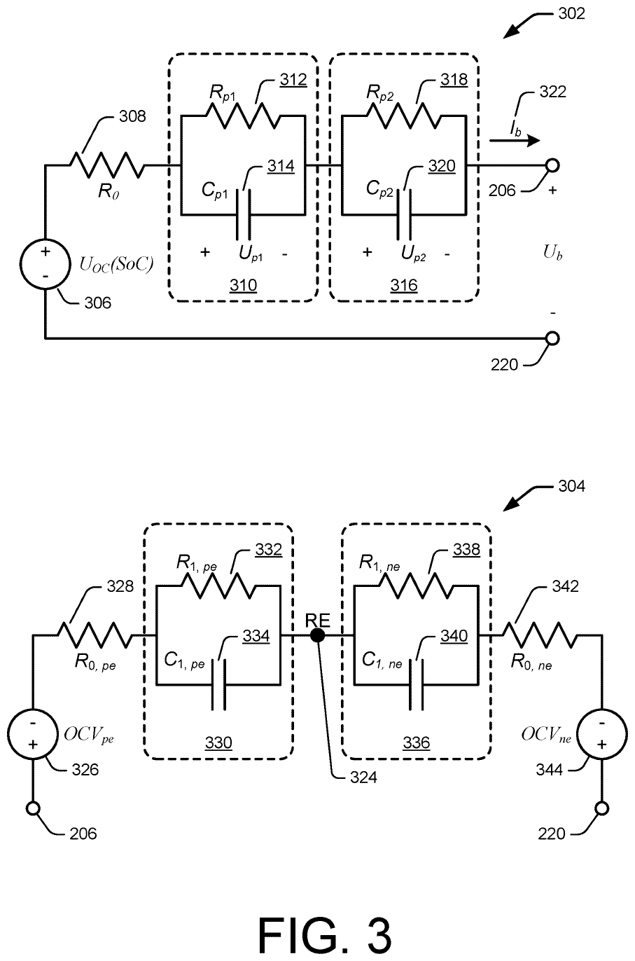

The component 230 may be represented by various model configurations. FIG. 3 illustrates example model configurations, ECNs 302 and 304, representing the component 230 comprising various model elements. The ECN 302 illustrates RC pairs, which may include one to many RC pairs, representing combined ECN elements. The example ECN 304 illustrates a split potential model for one RC pair. Split potential models are useful for modelling anode and cathode degradation separately and determining the resulting changes in open-circuit voltage used in the state-of-charge estimation methods described herein. Reference [3] details how split potential circuits (referred to as ‘half-cell’ models) can be incorporated into ECN models to account for distributed degradation. The distributed nature of the model allows the prediction of localized temperature hotspots resulting from inhomogeneous degradation. The theoretical basis is given in detail in Reference [4]. Reference [5] describes a method for incorporating the degradation caused by lithium plating into the split-potential model estimation framework.

The ECN 302 comprises a voltage source 306, representing an open circuit voltage U_{OC} of the SoC, connected to the negative node 220 on a negative terminal and to a resistor R₀ 308 on a positive terminal. The resistor R₀ 308 is coupled to a first RC pair 310 having a potential Uₚ₁ and comprising a resistor Rₚ₁ 312 in parallel with a capacitor Cₚ₁ 314. The first RC pair 310 is coupled to a second RC pair 316 having a potential Uₚ₂ and comprising a resistor Rₚ₂ 318 in parallel with a capacitor Cₚ₂ 320. The second RC pair 316 is coupled to the positive node 206. The ECN current, or a sub-model current, 232 for this model is shown as I_{b} 322.

The ECN 304 illustrates a split potential model that splits the potential difference between the positive node 206 and the negative node 220 at a point RE 324, which results in a potential vₚₑ between the positive node 206 and the point RE 324, and a potential vₙₑ between the point RE 324 and the negative node 206. The ECN 304 comprises a positive-side voltage source 326, representing a positive open circuit voltage OCVₚₑ, connected to the positive node 206 on a positive terminal and to a positive-side resistor R_{0,pe} 328 on a negative terminal. The positive-side resistor R_{0,pe} 328 is coupled to a positive-side RC pair 330 comprising a resistor R_{1,pe} 332 in parallel with a capacitor C_{1,pe} 334. The positive-side RC pair 330, at the point RE 324, is coupled to a negative-side RC pair 336 comprising a resistor R_{1,ne} 338 in parallel with a capacitor C_{1,ne} 340. The negative-side RC pair 336 is coupled to a negative-side resistor R_{0,ne} 342, which is coupled to a negative terminal of a negative-side voltage source 344. The negative-side voltage source 344 represents a negative open circuit voltage OCVₙₑ, and the positive terminal is connected to the negative node 220.

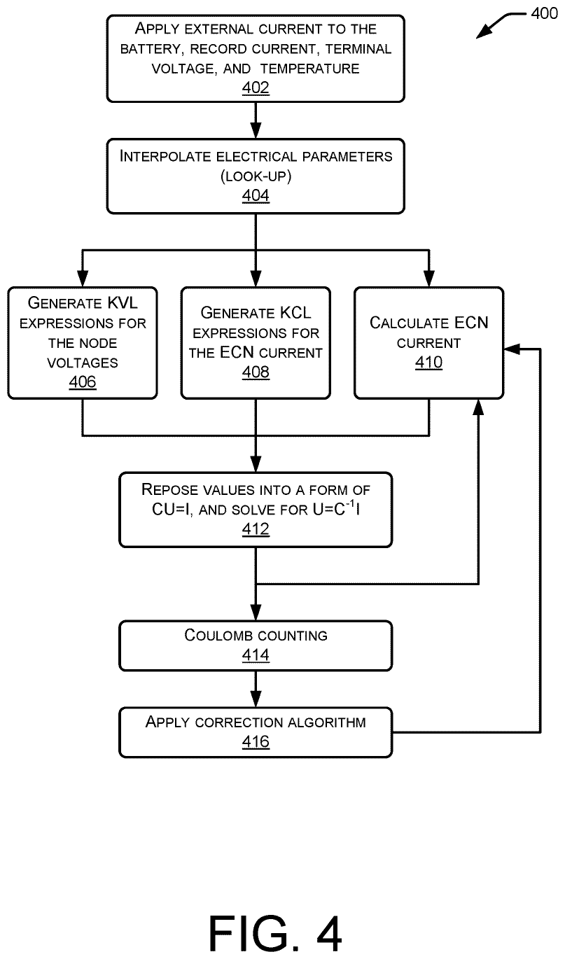

FIG. 4 illustrates a flow chart 400 representing an example process of calculating the SoC of the Li-Ion battery 104 based on the distributed electrical model ECN 106. At block 402, external current is applied to the Li-Ion battery 104 and the current, terminal voltage, and surface temperature of the prismatic jellyroll cell 102 are obtained and recorded.

At block 404, distributed electrical parameters are interpolated. For example, a state of charge (SoC) of the Li-Ion battery 104 may be determined based on the recorded voltage, current, and temperature, then distributed circuit parameters may be determined from a look-up table that charts parameter values according to the SoC and the temperature. The look-up table may be based on, or function of, the SoC and temperature, and may contain values of OCV, Ohmic resistance, RΩ, and RC parameters for each RC pair of the ECN considered. Next, based on the distributed circuit parameters, Kirchoff voltage law (KVL) expressions for the node voltages, such as Ø₁⁺ 204 and Ø₁⁻ 218 are generated at block 406; Kirchoff current law (KCL) expressions for the ECN current 232 is generated at block 408; and the ECN current 232 is calculated at block 410. Blocks 406, 408, and 410, may be performed in parallel or in series with any order.

At block 412, values, such as the KVL expressions, KCL expressions, and the RC-pair current, are provided and used to solve an electrical quantity vector U. For example, the values may be reposed into a form of CU=I, and the electrical quantity vector U may be solved as U=C⁻¹I. The electrical quantity vector U may consist of sub-model currents (one per ECN) and node voltages (two per ECN, +V_{E} and −V_{E}). The ECN current 232 from block 410 may be corrected or refined by utilizing an estimate correction/refinement algorithm (correction algorithm), including unscented Kalman filter algorithm and EKF algorithm, before used at block 412. Data associated with the electrical quantity vector U from block 412 may be provided to block 410 to refine the current calculation of the ECN current 232. At block 414, Coulomb counting is performed to calculate the SoC of the Li-Ion battery 104. For example, calculated terminal voltage and the sub-model current 232 may be extracted from the vector U, which may be integrated to calculate the SoC of the Li-Ion battery 104. At block 416, the algorithm may be applied to the calculated SoC values, i.e., a localized SoC of each ECN of the plurality of ECNs of the cell 102 calculated in the distributed electrical model, which may be fed back to block 410 and used for refining the calculation of the SoC of the Li-Ion battery 104.

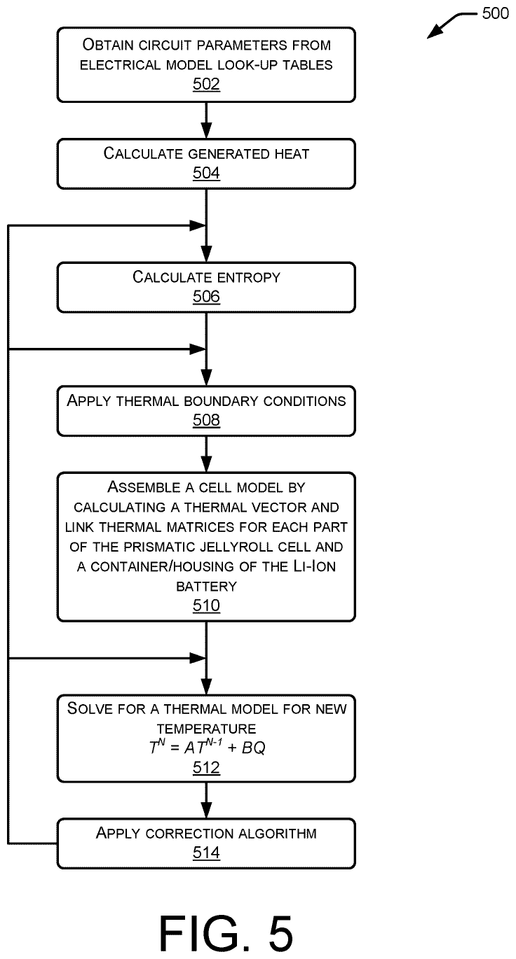

FIG. 5 illustrates a flow chart 500 representing an example process of thermal modeling of the Li-Ion battery 104 based on the distributed thermal model ECN elements 110. Heat generated may be calculated from the current and the node voltage difference determined using the distributed thermal model ECN elements 110. The process utilizes temperature from the last timestep Tₖ₋₁ and a vector of the heat generation uₖ₋₁ along with A and B thermal conductivity matrices to calculate a new surface temperature Tₖ through matrix inversion. The heat equation may be discretized using Crank-Nicholson method:

$$ρ c \frac{\partial T}{\partial r} = ∇ \cdot ( λ ∇ T ) + q = {λ}_{x} \frac{{\partial }^{2} T}{\partial {x}^{2}} + {λ}_{y} \frac{{\partial }^{2} T}{\partial {y}^{2}} + {λ}_{Z} \frac{{\partial }^{2} T}{\partial {z}^{2}} + {q}_{1}$$

where ρ is the heat density, c is the heat capacity, λ is the heat transfer coefficient, T is the temperature of the material, λₓ, λ_{y}, and λ_{c} are the heat transfer coefficients in the three directions, and q is the heat source. Further detail describing the temperature estimation process, which can estimate internal and surface temperatures is described in detail in References [2]& [6].

At block 502, circuit parameters for a segment, such as the segment 112, may be obtained from electrical model look-up tables, and the heat generated may be calculated at block 504 based on ohmic resistances and currents determined using the distributed thermal model ECN 110. At block 506, based on the circuit parameters obtained from the electrical model look-up tables and the heat generated calculated at block 504, entropy for the segment is calculated. At block 508, thermal boundary constraints, or conditions, for heat transfer and convection temperature are applied for surface cooling conditions. The Li-Ion battery 104 is assembled into a cell model by calculating a thermal vector and link thermal matrices for each segment of the prismatic jellyroll cell 102 and a container/housing of the Li-Ion battery 104 at block 510, and a thermal model for a new temperature is solved at block 512. For example, the solution may be in a form of:
T^{N}=AT^{N-1}+BQ. Q is a vector of heat generation (Joule heating) and entropy terms, Q=Qₕₑₐₜ+Q_{entropy}. Qₕₑₐₜ is calculated from the electrical vector terms for node voltage and the resistances from the look-up tables. Q_{entropy} is calculated from the differential of voltage with temperature, dV/dT, which is also looked up as a function of SoC. At block 514, correction is applied to T^{N}, i.e., a temperature of each of the plurality of ECNs calculated in the distributed thermal model, and the algorithm-corrected T^{N} is fed back to blocks 506, 508, and 512 for the next iteration.

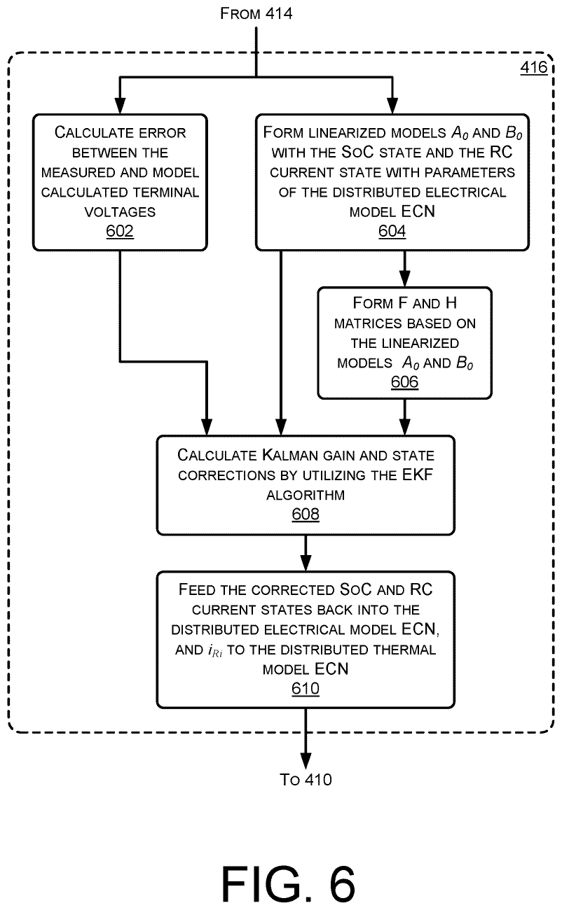

FIG. 6 illustrates an example process of block 416 of FIG. 4 for estimating the SoC states and the RC current states of the Li-Ion battery 104. At block 602, error between the measured terminal voltage and the model calculated terminal voltage may be determined. For example, a voltage difference between the terminal voltage recorded at block 402 and the terminal voltage calculated at block 414 may be calculated. At block 604, linearized model matrices A₀ and B₀ with the SoC state and the RC current state may be formed with parameters of the distributed electrical model ECN 106, and based the linearized models A₀ and B₀, an F matrix and an H matrix may be formed at block 606, where F matrix is the transition matrix and the H matrix is the observation matrix. At block 608, based on the calculated terminal voltage error, the linearized matrices A₀ and B₀, and the F and H matrices, Kalman gain and state corrections may be calculated by utilizing the correction algorithm. At block 610, the corrected SoC and RC current states may be fed back into the distributed electrical model ECN 106, and the ECN current 232 to the distributed thermal model ECN 110.

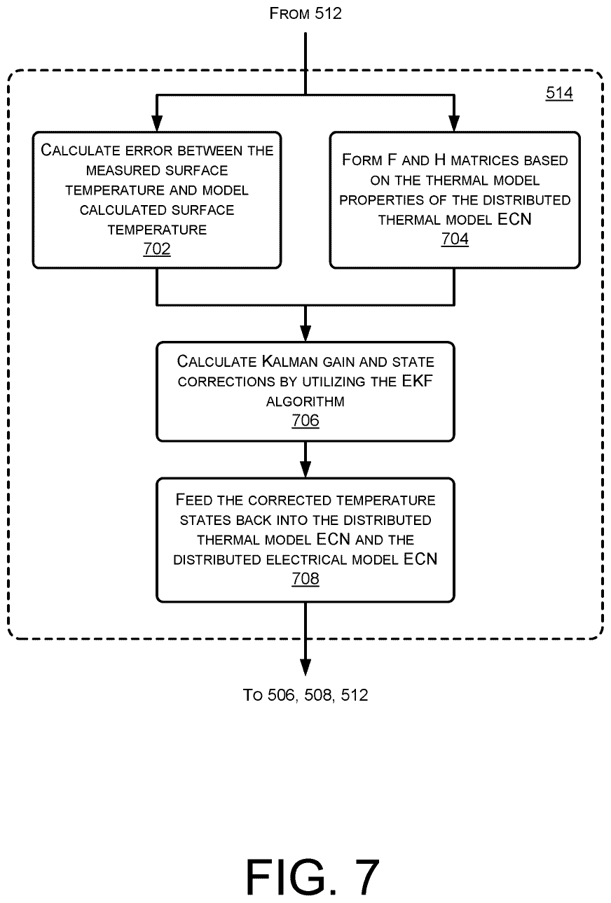

FIG. 7 illustrates a flow chart representing an example process of block 514 of FIG. 5 for estimating the temperature states of the Li-Ion battery 104. At block 702, error between the measured surface temperature and the model calculated temperature (model estimate temperature. i.e., the new temperature calculated at block 512) may be determined. At block 704, an F matrix and an H matrix may be formed offline based on the thermal model properties of the distributed thermal model ECN 110, where F matrix is the transition matrix and the H matrix is the observation matrix. At block 706, based on the calculated temperature error and the F and H matrices, Kalman gain and state corrections may be calculated by utilizing the EKF algorithm. At block 708, the corrected temperature states may be fed back into the distributed thermal model ECN 110 and the distributed electrical model ECN 106.

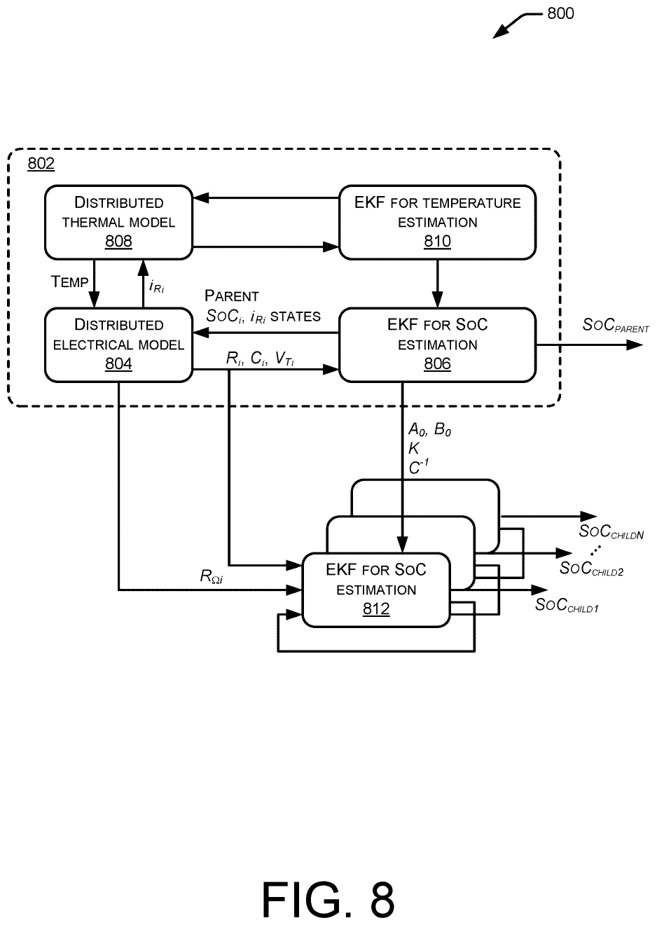

FIG. 8 illustrates a diagram 800 representing an example process of estimating the SoC of the parent cell and child cell(s) based on the distributed electrical model ECN 106 and the distributed thermal model ECN 110. The process of estimating the SoC of the parent cell is the same process as estimating the SoC of the prismatic jellyroll cell 102 of the Li-Ion battery 104 as described above with reference to FIGS. 1-7. For estimating the SoC of the child cell(s) in a Li-Ion battery, the parent cell and a plurality of child cells are assembled into a pack, and to track a child, or individual, cell SoC distribution, the following conditions may be assumed: 1) all cells are of the same type; 2) a sub-model current through each ECN of a plurality of ECNs of the plurality of child cells is about equal the sub-model current through an ECN of the plurality of ECNs of the parent cell; 3) the temperature of the parent cell surface is sufficiently close to the surface temperatures of all of the plurality of child cells; and 4) capacity and resistance degradation across the pack of the cells, including the parent cell and the plurality of child cells, is sufficiently similar.

Block 802 includes blocks 804, 806, 808, and 810 for the processes associated with calculating the parameters for the parent cell, for example, the prismatic jellyroll cell 102 of the Li-Ion battery 104, utilizing an estimate correction/refinement algorithm (correction algorithm), such as a un scented or full EKF algorithm based on the distributed electrical and thermal model calculations. At block 804, distributed electrical parameters associated with the SoC of the prismatic jellyroll cell 102 based on the distributed electrical model ECN may be calculated by performing the process described above with reference to FIG. 4. The calculated electrical parameters, such as Rᵢ, Cᵢ, and V_{Ti}, corresponding to segments, indicated by i, of the prismatic jellyroll cell 102, may be forwarded to block 806 at which the correction algorithm for the SoC estimation is performed by the process described above with reference to FIG. 6. The SoC, and i_{Ri} states from block 806 may be fed back to block 804 for refining Rᵢ, Cᵢ, and V_{Ti} values.

At block 808, the thermal model associated with the prismatic jellyroll cell 102 based on the distributed thermal ECN may be calculated by performing the process described above with reference to FIG. 5. The thermal model T_{S} of the prismatic jellyroll cell 102, may be forwarded to block 810 at which the correction algorithm for the temperature estimation is performed by the process described above with reference to FIG. 7. The corrected temperature vector \hat{T}_{XYZ} may be fed back to block 808 for refining the thermal model T_{S}. The corrected temperature vector \hat{T}_{XYZ} may also be input to the correction algorithm for the SoC estimation of block 806 for determining the SoC of the prismatic jellyroll cell 102 of the Li-Ion battery 104, which may be also used as the parent cell. Some information, or data, such as i_{Ri} states, corrected temperature, and electrical vector parameters from the lookup table(s) including resistance and calculated node voltages form U, are also exchanged between blocks 804 and 708.

To calculate the SoC of the plurality of child cells (the child cells), some data are passed from block 802, the calculation of the parent cell for the correction algorithm, such as unscented Kalman filter or EKF, for the SoC estimation of the child cells at block 812. For example, from block 806, the linearized model matrices A₀ and B₀, the Kalman gain K matrix, and the inverted matrix C⁻¹ are passed to block 812 for the EKF for the SoC estimation of the child cells. Child cell states, such as child SoCᵢ and i_{Ri} states may then be calculated from a general cell distribution model based on the assumptions discussed above, and used for calculating child terminal voltages for individual cell SoC corrections. This process is repeated for estimating all distributed electrical information for all cells.

Alternatively, the parent cell (102) may be considered as the average across a group of cells, such as child cells, in series such as those found in a module or string. Accordingly, for a module, the mean of all measured voltages may be used to form the parent measurement. The full electro-thermal model and EKF may be iterated for the parent measurement, i.e., the average, only. The current in each child cell in the module may be assumed to be the same, and only the module current need to be measured. The linearized model from the parent EKF may then be used, as well as the Kalman gain, to iterate a separate EKF for each child cell in the module based on its measured voltage. Therefore, the distributed process may more efficiently estimate the SoC for each cell than running the entire process for each cell, and also maintain accuracy.

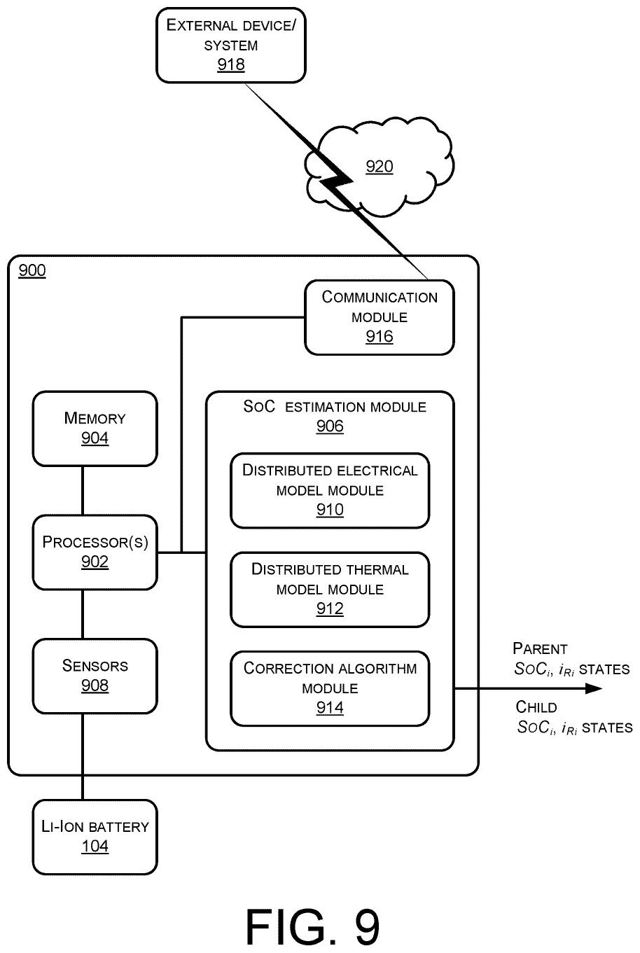

FIG. 9 illustrates a block diagram of an example SoC estimation system 900. The SoC estimation system may comprise one or more processors, for example, processor(s) 902, communicatively coupled to memory 904. The processor(s) 902 may include one or more central processing units (CPUs), graphics processing units (GPUs), both CPUs and GPUs, or other processing units or components known in the art. The processor(s) 902 may execute computer-executable instructions stored in the memory 904 to perform functions or operations with one or more of components, or modules, communicatively coupled to the processor(s) 902. Computer-readable media, such as memory 904 may include volatile memory (e.g., RAM), non-volatile memory (e.g., ROM, flash memory, miniature hard drive, memory card, or the like), or some combination thereof. The computer-readable media may be non-transitory computer-readable media. The computer-readable media may include or be associated with the one or more of the above-noted modules, which perform various operations associated with the SoC estimation system 900. In some examples, one or more of the modules may include or be associated with computer-executable instructions that are stored by the computer-readable media and that are executable by one or more processors to perform such operations. Additionally, the processor(s) 902 may possess its own local memory, which also may store program modules, program data, and/or one or more operating systems.

The one or more of components, or modules, may include an SoC estimation module 906, which may provide estimation of the SoC of a Li-Ion battery, such as the Li-Ion battery 104 connected to the SoC estimation system 900 via one or more sensors 908 of the SoC estimation system 900. The SoC estimation module 906 may include a distributed electrical model module 910, a distributed thermal model module 912, and an estimate correction/refinement algorithm (correction algorithm) module 914. While the SoC estimation module 906 is shown as a separate module in this example, the SoC estimation module 906 may be included in the memory 904 as computer executable module or instructions. Based on parameters of the Li-Ion battery 104, such as the terminal voltage, current, and temperature, obtained and provided by the one or more sensors 908, the SoC estimation module 906 may calculate the SoC estimation of the Li-Ion battery 104 and, if the Li-Ion battery 104 included a plurality of cells, the SoC of the child cells of the Li-Ion battery 104. For example, the distributed electrical model module 910 may calculate i_{Ri} of each segment of the prismatic jellyroll cell 102 of the Li-Ion battery 104 as described above with reference to FIG. 4, and the distributed thermal model module 912 may calculate temperature of each segment of the prismatic jellyroll cell 102 as described above with reference to FIG. 5. The correction algorithm module 914 may receive the calculated i_{Ri} and temperature from the distributed electrical model module 910 and the distributed thermal model module 912 and apply corrections, such as unscented Kalman filter or EKF, to the calculated i_{Ri} and temperature. The correction algorithm module 914 may feed the corrected i_{Ri}, corrected SoC, and temperature back to the distributed electrical model module 910 and the distributed thermal model module 912 for further refinement, and provide the SoC estimation of the Li-Ion battery 104 and, if the Li-Ion battery 104 included a plurality of cells, the SoC of the child cells of the Li-Ion battery 104 as described above with reference to FIG. 6-8.

The SoC estimation system 900 may additionally include a communication module 916 for communicating an external, or a remote, computing device or system 918 associated with the SoC estimation system 900. The communication module 916 may communicate with the external device/system 918 via a wired or wireless communication network 920, such as the Internet, a cellular network, local area network (LAN), wireless LAN (WLAN), and the like. The communication module 916 may transmit data or information collected or calculated by the SoC estimation system to the external device/system 918, and may receive instructions and data from the external device/system 918 regarding the Li-Ion battery 104 and the SoC estimation process.

### INDUSTRIAL APPLICABILITY

The example systems and methods of the present disclosure are applicable to a lithium-ion (Li-Ion) batteries. The systems and methods described herein may be utilized to estimate state of charge (SoC) of Li-Ion batteries.

For example, a system for estimating SoC of a Li-Ion battery using embedded distributed electro-thermal models includes one or more processors; a SoC estimation module coupled to the one or more processors; one or more sensors coupled to the one or more processors; and memory coupled to the one or more processors, where the memory stores thereon computer executable instructions that, when executed by the one or more processors, cause the one or more processors to perform operations for estimating the SoC of the Li-Ion battery. A distributed electrical model of a cell of a lithium-ion (Li-Ion) battery and a distributed thermal model of the Li-Ion battery are generated where the cell is a parent cell and the Li-Ion battery includes a plurality of child cells packaged with the parent cell in a pack. Corrections are applied to a localized SoC of each ECN of a plurality of ECNs of the cell calculated in the distributed electrical model and to a temperature of each of the plurality of ECNs calculated in the distributed thermal model. The SoCs of the plurality of ECNs are refined by feeding the corrected localized SoCs and the corrected localized temperatures back to the distributed electrical model and the distributed thermal model, and an SoC estimation of the cell of the Li-Ion battery is generated based on the refined SoCs. A child cell SoC of each of the plurality of child cells is calculated by applying calculated parameters associated with the SoC estimation of the parent cell to a general cell distribution model, applying correction to the child cell SoC of each of the plurality of child cells by applying a correction algorithm to the child cell SoC of each of the plurality of child cells, and generating a child SoC estimation of each child cell of the plurality of child cells based on the corrected child cell SoC of each of the plurality of child cells.

Unless explicitly excluded, the use of the singular to describe a component, structure, or operation does not exclude the use of plural such components, structures, or operations or their equivalents. The use of the terms “a” and “an” and “the” and “at least one” or the term “one or more,” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B” or one or more of A and B”) is to be construed to mean one item selected from the listed items (A or B) or any combination of two or more of the listed items (A and B; A, A and B; A, B and B), unless otherwise indicated herein or clearly contradicted by context. Similarly, as used herein, the word “or” refers to any possible permutation of a set of items. For example, the phrase “A, B, or C” refers to at least one of A, B, C, or any combination thereof, such as any of A; B; C; A and B; A and C; B and C; A, B, and C; or multiple of any item such as A and A; B, B, and C; A, A, B, C, and C; etc.

While aspects of the present disclosure have been particularly shown and described with reference to the examples above, it will be understood by those skilled in the art that various additional embodiments may be contemplated by the modification of the disclosed devices, systems, and methods without departing from the spirit and scope of what is disclosed. Such embodiments should be understood to fall within the scope of the present disclosure as determined based upon the claims and any equivalents thereof.

### REFERENCES

1. The Co-estimation of State of Charge, State of Health, and State of Function for Lithium-Ion Batteries in Electric Vehicles, Chinese Patent No. 105301509B, Shen Ping et al, 29 Mar. 2019
2. Python-based Equivalent Circuit Network (PyECN) Modelling Framework for Lithium-ion Batteries, engrxiv preprint, Imperial College London: Shen Li, Sunil Rawat, Tao Zhu, Monica Marinescu, Gregory Offer, Apr. 24, 2023
3. Real-time estimation of negative electrode potential and state of charge of lithium-ion battery based on a half-cell-level equivalent circuit model, Journal of Energy Storage: Volume 51, Cheng Zhang, Tazdin Amietszajew, Shen Li, Monica Marinescu, Gregory Offer, Chongming Wang, Yue Guo, Rohit Bhagat, 2022
4. Effect of thermal gradients on inhomogeneous degradation in lithium-ion batteries, Nature Commun Eng 2, 74 (2023). https://doi.org/10.1038/s44172-023-00124-w, Imperial College London: Shen Li, Cheng Zhang, Yan Zhao, Gregory Offer, Monica Marinescu, Sep. 29, 2023.
5. Modelling inhomogeneous lithium plating with a distributed equivalent circuit network, poster submitted to ModVal, OBMS and Advanced Battery Power conferences, Spring 2023, Thomas J. Holland, Simon E. J. O'Kane, Shen Li, Niall D. Kirkaldy, Gregory J. Offer, Monica Marinescu
6. Internal Temperature Estimation for Lithium-ion Batteries Through Distributed Equivalent Circuit Network Model, engrxiv preprint, Imperial College London: Shen Li, Anisha N. Patel, Cheng Zhang, Tazdin Amietszajew, Niall Kirkaldy, Gregory J. Offer, Monica Marinescu, Sep. 29, 2023

What is claimed is:

1. A method comprising:
generating a distributed electrical model (804) of a cell (102) of a lithium-ion (Li-Ion) battery (104), the cell being a parent cell and the Li-Ion battery including a plurality of child cells packaged with the parent cell in a pack;
generating a distributed thermal model (808) of the cell;
applying corrections (806) to a localized state of charge (SoC) of each equivalent circuit network (ECN) of a plurality of ECNs of the cell calculated in the distributed electrical model and to a localized temperature of each of the plurality of ECNs calculated in the distributed thermal model;
refining (416, 514) the SoCs of the plurality of ECNs by feeding the corrected localized SoCs and the corrected localized temperatures back to the distributed electrical model and the distributed thermal model;
generating (806) an SoC estimation of the cell based on the refined SoCs;
calculating (806) a child cell SoC of each of the plurality of child cells by applying calculated parameters associated with the SoC estimation of the parent cell to a general cell distribution model;
applying (812) correction to the child cell SoC of each of the plurality of child cells by applying a correction algorithm to the child cell SoC of each of the plurality of child cells; and
generating (812) a child SoC estimation of each child cell of the plurality of child cells based on the corrected child cell SoC of each of the plurality of child cells.

2. The method of claim 1, wherein:
an ECN of the plurality of ECNs represents a segment of a plurality of segments of the cell, and
an SoC of the cell is calculated based on integrating a sub-model current of each ECN of a plurality of ECNs over the plurality of segments.

3. The method of claim 1, wherein generating the distributed electrical model includes:
determining distributed electrical parameters of each ECN of the plurality of ECNs from a look-up table charting parameter values according to a corresponding localized SoC and a corresponding localized temperature.

4. The method of claim 3, wherein:
the distributed electrical parameters include a terminal voltage and a sub-model current of each ECN of a plurality of ECNs of the cell.

5. The method of claim 4, further comprising:
for each ECN of the plurality of ECNs of the cell, calculating (702) a temperature error between the localized temperature and a model estimate temperature;
forming (704) a second transition matrix and a second observation matrix based on properties of a distributed thermal model ECN; and
based on the temperature errors, the second transition matrix, and the second observation matrix, calculating (706) a Kalman gain and state corrections for the model estimate temperature of each ECN of the plurality of ECNs by utilizing the correction algorithm.

6. The method of claim 5, wherein conditions of the general cell distribution model include:
a type of the child cell is similar to a type of the parent cell,
a sub-model current through an ECN of a plurality of ECNs of the child cell is about equal to the sub-model current through an ECN of the plurality of ECNs of the parent cell,
surface temperature of the child cell is about equal to surface temperature of the parent cell, and
capacity and resistance degradation of the child cell are similar to capacity and resistance degradation of the parent cell.

7. The method of claim 6, wherein the calculated parameters associated with the SoC estimation of the parent cell include a first transition matrix, a first observation matrix, the second transition matrix, the second observation matrix, and the Kalman gains of the parent cell.

8. A system (900) comprising:
one or more processors (902);
a state of charge (SoC) estimation module (906) coupled to the one or more processors;
one or more sensors (908) coupled to the one or more processors; and
memory (904) coupled to the one or more processors, the memory storing thereon computer executable instructions that, when executed by the one or more processors, cause the one or more processors to perform operations comprising:
generating, by a distributed electrical model module (910) of the SoC estimation module, a distributed electrical model (804) of a cell of a lithium-ion (Li-Ion) battery (104), the cell being a parent cell and the Li-Ion battery including a plurality of child cells packaged with the parent cell in a pack;
generating, by a distributed thermal model module (912) of the SoC estimation module, a distributed thermal model (808) of the cell;
applying corrections (806), by a correction algorithm module (914), to a localized state of charge (SoC) of each equivalent circuit network (ECN) of a plurality of ECNs of the cell calculated in the distributed electrical model and to a localized temperature of each of the plurality of ECNs calculated in the distributed thermal model;
refining (416, 514) the SoCs of the plurality of ECNs by feeding the corrected localized SoCs and the corrected localized temperatures back to the distributed electrical model and the distributed thermal model;
generating (806) an SoC estimation of the cell based on the refined SoCs;
calculating (806) a child cell SoC of each of the plurality of child cells by applying calculated parameters associated with the SoC estimation of the parent cell to a general cell distribution model;
applying (812) correction to the child cell SoC of each of the plurality of child cells by applying a correction algorithm to the child cell SoC of each of the plurality of child cells; and
generating (812) a child SoC estimation of each child cell of the plurality of child cells based on the corrected child cell SoC of each of the plurality of child cells.

9. The system of claim 8, wherein:
an ECN of the plurality of ECNs represents a segment of a plurality of segments of the cell, and
an SoC of the cell is calculated based on integrating a sub-model current of each ECN of a plurality of ECNs the plurality of segments.

10. The system of claim 8, wherein generating the distributed electrical model includes:
determining distributed electrical parameters of each ECN of the plurality of ECNs from a look-up table charting parameter values according to a corresponding localized SoC and a corresponding localized temperature.

11. The system of claim 10, wherein:
the distributed electrical parameters include a terminal voltage and a sub-model current of each ECN of a plurality of ECNs of the cell.

12. The system of claim 11, wherein the operations further comprise:
for each ECN of the plurality of ECNs of the cell, calculating (702) a temperature error between the localized temperature and a model estimate temperature;
forming (704) a second transition matrix and a second observation matrix based on properties of a distributed thermal model ECN; and
based on the temperature errors, the second transition matrix, and the second observation matrix, calculating (706) a Kalman gain and state corrections for the model estimate temperature of each ECN of the plurality of ECNs by utilizing the correction algorithm.

13. The system of claim 12, wherein conditions of the general cell distribution model include:
a type of the child cell is similar to a type of the parent cell,
a sub-model current through an ECN of a plurality of ECNs of the child cell is about equal to the sub-model current through an ECN of the plurality of ECNs of the parent cell, surface temperature of the child cell is about equal to surface temperature of the parent cell, and
capacity and resistance degradation of the child cell are similar to capacity and resistance degradation of the parent cell.

14. The system of claim 13, wherein the calculated parameters associated with the SoC estimation of the parent cell include a first transition matrix, a first observation matrix, the second transition matrix, the second observation matrix, and the Kalman gains of the parent cell.

15. A non-transitory computer-readable storage medium storing thereon computer executable instructions that, when executed by one or more processors, cause the one or more processors to perform operations comprising:
generating a distributed electrical model (804) of a cell (102) of a lithium-ion (Li-Ion) battery (104), the cell being a parent cell and the Li-Ion battery including a plurality of child cells packaged with the parent cell in a pack;
generating a distributed thermal model (708) of the cell;
applying corrections (806) to a localized state of charge (SoC) of each equivalent circuit network (ECN) of a plurality of ECNs of the cell calculated in the distributed electrical model and to a localized temperature of each of the plurality of ECNs calculated in the distributed thermal model;
refining (416, 514) the SoC s of the plurality of ECNs by feeding the corrected localized SoCs and the corrected localized temperatures back to the distributed electrical model and the distributed thermal model;
generating (806) an SoC estimation of the cell based on the refined SoCs;
calculating (806) a child cell SoC of each of the plurality of child cells by applying calculated parameters associated with the SoC estimation of the parent cell to a general cell distribution model;
applying (812) correction to the child cell SoC of each of the plurality of child cells by applying a correction algorithm to the child cell SoC of each of the plurality of child cells; and
generating (812) a child SoC estimation of each child cell of the plurality of child cells based on the corrected child cell SoC of each of the plurality of child cells.

16. The non-transitory computer-readable storage medium of claim 15, wherein:
an ECN of the plurality of ECNs represents a segment of a plurality of segments of the cell, and
an SoC of the cell is calculate based on integrating a sub-model current of each ECN of a plurality of ECNs over the plurality of segments.

17. The non-transitory computer-readable storage medium of claim 15, wherein generating the distributed electrical model includes:
determining distributed electrical parameters of each ECN of the plurality of ECNs from a look-up table charting parameter values according to a corresponding localized SoC and a corresponding localized temperature.

18. The non-transitory computer-readable storage medium of claim 17, wherein:
the distributed electrical parameters include a terminal voltage and a sub-model current of each ECN of a plurality of ECNs of the cell.

19. The non-transitory computer-readable storage medium of claim 18, the operations further comprise:
for each ECN of the plurality of ECNs of the cell, calculating (702) a temperature error between the localized temperature and a model estimate temperature;
forming (704) a second transition matrix and a second observation matrix based on properties of a distributed thermal model ECN; and
based on the temperature error, the second transition matrix, and the second observation matrix, calculating (706) a Kalman gain and state corrections for the model estimate temperature of each ECN of the plurality of ECNs by utilizing the correction algorithm.

20. The non-transitory computer-readable storage medium of claim 19, wherein conditions of the general cell distribution model include:
a type of the child cell is similar to a type of the parent cell,
a sub-model current through an ECN of a plurality of ECNs of the child cell is about equal to the sub-model current through an ECN of a plurality of ECNs of the parent cell,
surface temperature of the child cell is about equal to surface temperature of the parent cell, and
capacity and resistance degradation of the child cell are similar to capacity and resistance degradation of the parent cell.
